(19) United States
(12) Patent Application Publication
(10) Pub. No.: US 2024/0429017 A1
(43) Pub. Date: Dec. 26, 2024

(54) ELECTRON BEAM POSITION DETECTION AND REPOSITIONING

(71) Applicant: KLA Corporation, Milpitas, CA (US)

(72) Inventors: Henning Stoschus, Wetzlar (DE); Jan Lehnert, Weilburg (DE)

(21) Appl. No.: 18/641,360

(22) Filed: Apr. 20, 2024

Related U.S. Application Data
(60) Provisional application No. 63/522,185, filed on Jun. 21, 2023.

(51) Int. Cl. H01J 37/147; H01J 37/28

(52) U.S. Cl. CPC H01J 37/1472; H01J 37/28; H01J 2237/151

(57) ABSTRACT

A multichannel electrode tube includes at least four deflection plates. Each of the deflection plates is disposed opposite another of the deflection plates across the path of an electron beam that passes through the multichannel electrode tube. A voltage difference between of a pair of the deflection plates that are arranged opposite each other across the path of the electron beam is determined. A position of the electron beam in the multichannel electrode tube is then determined based on the voltage difference.

### CROSS-REFERENCE TO RELATED APPLICATIONS

This application claims priority to the provisional patent application filed Jun. 21, 2023 and assigned U.S. App. No. 63/522,185, the disclosure of which is hereby incorporated by reference.

### FIELD OF THE DISCLOSURE

This disclosure relates to workpiece inspection using an electron beam.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

Electron beam systems, such as scanning electron microscopes (SEMs), can be used for metrology. In these electron beam systems, an electron beam must be accurately directed to a target. In addition, systems that use high power electron beams must be aligned so that the electron beam does not damage electron optical components or accidently irradiate working surfaces in unwanted locations. While electron beam systems can be aligned manually by a technician, this can be complex, lengthy, and expensive. Manual approaches can be subjective such that alignment varies depending on which technician performs the alignment.

Electron beams in SEMs and other electron beam inspection systems also suffer from problems caused by unknown electron beam position within the electron beam column housing or scanning area. Drift compensations rely on interferometers to measure relative distance between the electron beam column housing and the stage. Drifts between the electron beam column housing and the stage are compensated. Because there are no detectors that detect and compensate for beam position, drift of the absolute electron beam position relative to the electron beam column housing cannot be detected. Therefore, improved systems and techniques are needed.

### BRIEF SUMMARY OF THE DISCLOSURE

A system is provided in a first embodiment. The system includes an electron beam source that generates an electron beam; a stage configured to hold a workpiece in a path of the electron beam; a multichannel electrode tube that includes at least four deflection plates; a power source in electronic communication with the deflection plates; and a processor in electrical communication with the deflection plates. Each of the deflection plates is disposed opposite another of the deflection plates across the path of the electron beam in the multichannel electrode tube. The processor is configured to determine a voltage difference between of a pair of the deflection plates that are arranged opposite each other across the path of the electron beam and determine a position of the electron beam in the multichannel electrode tube based on the voltage difference.

The deflection plates can be arranged as a square around the path of the electron beam.

In an instance, there are eight of the deflection plates. The deflection plates can have an octagonal configuration around the path of the electron beam.

The position may be in a cross-sectional plane of the multichannel electrode tube perpendicular to the path of the electron beam.

The processor can be further configured to: determine a gap between the position of the electron beam in the multichannel electrode tube and a position specification for the electron beam in the multichannel electrode tube; determine a voltage scheme for the multichannel electrode tube that directs the electron beam to the position specification; and send instructions to the power source to apply the voltage scheme to the deflection plates. The position specification may be a center of the multichannel electrode tube. Two of the deflection plates can used to measure voltages for the voltage difference and a different two of the deflection plates can receive the voltage scheme.

A method is provided in a second embodiment. The method includes generating an electron beam using an electron beam source. The electron beam is directed toward a workpiece on a stage. The electron beam is directed through a multichannel electrode tube. The multichannel electrode tube includes at least four deflection plates. Each of the deflection plates is disposed opposite another of the deflection plates across a path of the electron beam. A voltage difference between of a pair of the deflection plates that are arranged opposite each other across the path of the electron beam is determined. Using a processor, a position of the electron beam in the multichannel electrode tube is determined based on the voltage difference.

The deflection plates may be arranged as a square around the path of the electron beam.

In an instance, there are eight of the deflection plates. The deflection plates can have an octagonal configuration around the path of the electron beam.

The position may be in a cross-sectional plane of the multichannel electrode tube perpendicular to the path of the electron beam.

The method can further include: determining, using the processor, a gap between the position of the electron beam in the multichannel electrode tube and a position specification for the electron beam in the multichannel electrode tube; determining, using the processor, a voltage scheme for the multichannel electrode tube that directs the electron beam to the position specification; and applying the voltage scheme to the deflection plates. The position specification may be a center of the multichannel electrode tube. Two of the deflection plates can be used to measure voltages for the voltage difference and a different two of the deflection plates can be used with the voltage scheme.

A non-transitory computer-readable storage medium is provided in a third embodiment. The non-transitory computer-readable storage medium includes one or more programs for executing steps on one or more computing devices. The steps include receiving voltage measurements for a pair of deflection plates in a multichannel electrode tube as an electron beam is directed through the multichannel electrode tube, determining a voltage difference between of the pair of the deflection plates; and determining a position of the electron beam in the multichannel electrode tube based on the voltage. Each of the deflection plates is disposed opposite another of the deflection plates across a path of the electron beam.

The steps may further include: determining a gap between the position of the electron beam in the multichannel electrode tube and a position specification for the electron beam in the multichannel electrode tube; determining a voltage scheme for the multichannel electrode tube that directs the electron beam to the position specification; and sending instructions to apply the voltage scheme to the deflection plates.

### DESCRIPTION OF THE DRAWINGS

For a fuller understanding of the nature and objects of the disclosure, reference should be made to the following detailed description taken in conjunction with the accompanying drawings, in which:

FIG. 1 is a block diagram of a system in accordance with the present disclosure;

FIG. 2 is a cross-sectional diagram of an embodiment of a multichannel electrode tube in accordance with the present disclosure;

FIG. 3 is a cross-sectional diagram of another embodiment of a multichannel electrode tube in accordance with the present disclosure;

FIGS. 4-6 include voltage charts showing operation of the multichannel electrode tube corresponding to the embodiment of FIG. 3 as the electron beam moves over time; and

FIGS. 7 and 8 include charts showing operation of the multichannel electrode tube corresponding to the embodiment of FIG. 3.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein detect and compensate for electron beam positioning errors in an electron beam inspection system. Determining absolute electron beam placement and position measurement relative to the electron beam column housing can provide more accurate registration measurements in the electron beam inspection system. Measuring electron beam absolute position with respect to the electron beam column housing enables registration measurement on a sub-nanometer level, which is not possible using an interferometer and electron beam steering.

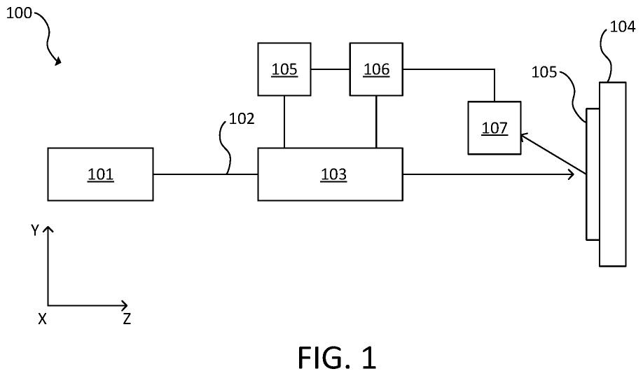

FIG. 1 is a block diagram of an electron beam system 100. The system includes an electron beam source 101 that generates an electron beam 102. The electron beam 102 is directed toward a workpiece 105 that is held on a stage 104. The electron beam 102 can be used to generate images of the workpiece 105, which can be used for inspection of the workpiece 105.

The electron beam source 101 may include, for example, a cathode source or emitter tip. The electron beam source 101 may be coupled with other elements, such as a gun lens, an anode, a beam limiting aperture, a gate valve, a beam current selection aperture, an objective lens, or a scanning subsystem, all of which may include any such suitable elements known in the art.

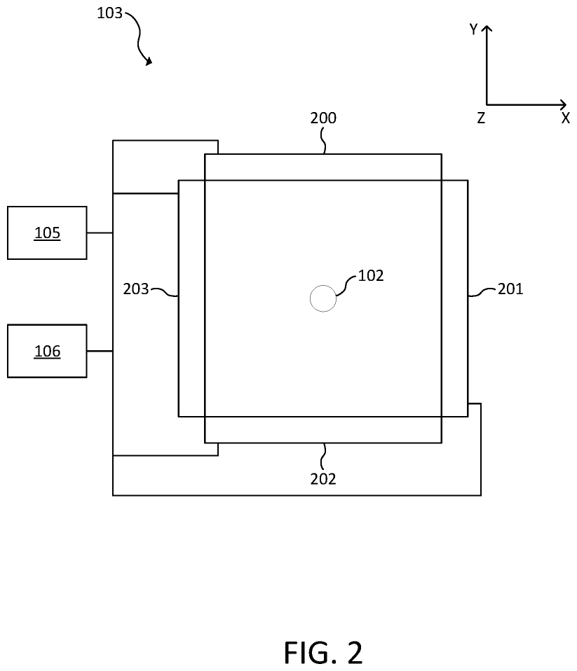

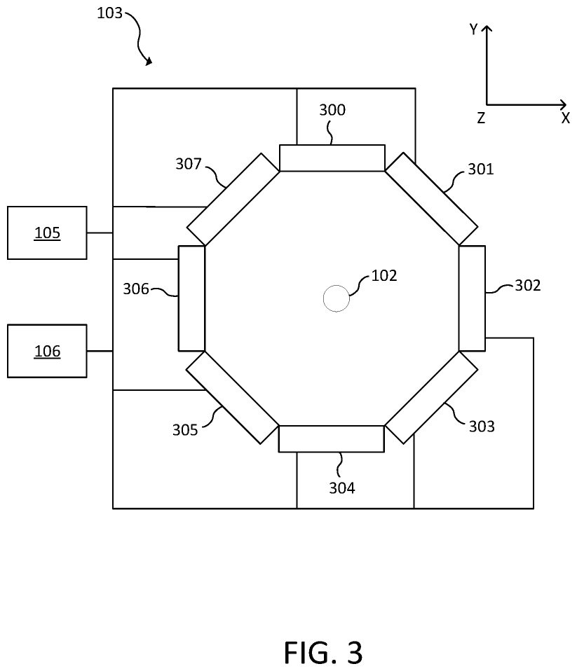

The electron beam 102 is directed through a multichannel electrode tube 103. The multichannel electrode tube 103 can include at least four deflection plates, as shown in FIGS. 2 and 3. Each of the deflection plates in the multichannel electrode tube 103 is disposed opposite another of the deflection plates across the path of the electron beam 102. The deflection plates in the multichannel electrode tube 103 are in electronic communication with a power source 105 and a processor 106. The processor 106 also can be in electronic communication with the power source 105.

While four deflection plates are illustrated in FIG. 2 and eight deflection plates are illustrated in FIG. 3, other numbers of deflection plates are possible. For example, six, ten, twelve, fourteen, or sixteen deflection plates may be used. There are at least two deflection plates (i.e., a pair) in each perpendicular axial direction around the electron beam 102. In an instance, there are an even number of deflection plates, and the deflection plates are grouped in pairs across the path of the electron beam 102. The deflection plates may have the same dimensions or different dimensions. The deflection plates that are opposite each other across the electron beam 102 may have the same dimensions.

Electrons returned from the workpiece 105 (e.g., secondary electrons) may be focused by one or more elements to a detector 107 to image the workpiece 105. The one or more elements may include, for example, a scanning subsystem. The detector 107 can be in electronic communication with the processor 106.

The various components of the electron beam system 100 can be positioned inside a vacuum chamber. The electron beam 102 may be generated during vacuum or near-vacuum conditions. The vacuum chamber can be, for example, an electron column.

FIG. 2 is a cross-sectional diagram of an embodiment of a multichannel electrode tube 103. As seen in FIG. 2, the multichannel electrode tube 103 includes four deflector plates 200-203 arranged as a square. Deflector plate 200 is opposite from deflector plate 202 relative to the electron beam 102. Deflector plate 201 is opposite from deflector plate 203 relative to the electron beam 102. Each of the deflector plates 200-203 is in electronic communication with the power source 105 and the processor 106. The electron beam 102 projects through the multichannel electrode tube 103 (i.e., the z axis shown in the figures).

FIG. 3 is a cross-sectional diagram of another embodiment of a multichannel electrode tube 103. As seen in FIG. 3, the multichannel electrode tube 103 includes eight deflector plates 300-307 arranged in an octagonal configuration. Deflector plate 300 is opposite from deflector plate 304 relative to the electron beam 102. Deflector plate 301 is opposite from deflector plate 305 relative to the electron beam 102. Deflector plate 302 is opposite from deflector plate 306 relative to the electron beam 102. Deflector plate 303 is opposite from deflector plate 307 relative to the electron beam 102. Each of the deflector plates 300-307 is in electronic communication with the power source 105 and the processor 106. The electron beam 102 projects through the multichannel electrode tube 103 (i.e., the z axis shown in the figures).

While FIG. 2 illustrates four deflector plates 200-203 and FIG. 3 illustrates eight deflector plates 300-307, other numbers of deflector plates may be used. The multichannel electrode tube 103 has an even number of deflector plates so that each deflector plate is opposite another of the deflector plates relative to the electron beam 102. The deflector plates can be arranged in a polygonal or circular shape.

The processor 106 can be communicatively coupled to a power source 105 and/or the deflector plates. The processor 106 may include one or more processors configured to execute any of various process steps. In embodiments, the processor 106 is configured to generate and provide one or more control signals configured to perform one or more adjustments to one or more deflector plates.

The one or more processors of the processor 106 may include any processor known in the art. For the purposes of the present disclosure, the term “processor” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program configured to operate or operate in conjunction with the electron beam system 100, as described throughout the present disclosure. Moreover, different subsystems of the electron beam system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single processor or, alternatively, multiple processors. Additionally, the processor 106 may include one or more processors housed in a common housing or within multiple housings. In this way, any processor 106 or combination of processors 106 may be separately packaged as a module suitable for integration into the electron beam system 100. Further, the processor 106 may analyze data received from the electron beam system 100 and feed the data to additional components within the electron beam system 100 or external to the electron beam system 100.

A memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive and the like. It is further noted that memory medium may be housed in a common processor housing with the one or more processors. In one embodiment, the memory medium may be located remotely with respect to the physical location of the one or more processors. For instance, the one or more processors of processor 106 may access a remote memory (e.g., server), accessible through a network (e.g., internet, intranet, and the like).

A user interface can be communicatively coupled to the processor 106. In embodiments, the user interface includes a display used to display data of the electron beam system 100 to a user. The display of the user interface may include any display known in the art. For example, the display may include, but is not limited to, a liquid crystal display (LCD), an organic light-emitting diode (OLED) based display, or a cathode ray tube (CRT) display. Those skilled in the art should recognize that any display device capable of integration with a user interface is suitable for implementation in the present disclosure. In embodiments, a user may input selections and/or instructions responsive to data displayed to the user via a user input device of the user interface.

The processor 106 can determine a voltage difference between of a pair of the deflection plates that are arranged opposite each other across the path of the electron beam 102 (e.g., deflection plates 200 and 202 or deflection plates 303 and 307). The electron beam 102 can induce a charge on the deflection plates using the physics effect of mirror charges. One or more voltmeters can be used to measure the voltage difference on a pair of the deflection plates. Information from the voltmeters can be communicated to the processor 106. The voltage difference indicates a position of the electron beam 102 between the pair of the deflection plates. The processor 106 can then determine a position of the electron beam 102 in the multichannel electrode tube 103 based on the voltage difference. When the voltage difference is zero, then the electron beam 102 is in the center of the multichannel electrode tube 103 (e.g., in the x-y plane). A function to convert the voltage difference to a distance (e.g., 1-100 μm) away from the center can be determined for a particular tool and/or for particular parameters of the electron beam 102. In another example, the position of the electron beam 102 in the multichannel electrode tube 103 is center/not centered or zero/not zero between the pair of deflection plates without a particular distance away from the center.

In an embodiment, the processor 106 also can determine a gap between the position of the electron beam 102 in the multichannel electrode tube 103 and a position specification for the electron beam 102 in the multichannel electrode tube 103. The processor can then determine a voltage scheme for the multichannel electrode tube 103 that directs the electron beam 102 to the position specification and can send instructions to the power source 105 to apply the voltage scheme to the deflection plates. The specification may be, for example, a center of the multichannel electrode tube 103. In an instance, two of the deflection plates are used to measure voltages for the voltage difference and a different two of the deflection plates receive the voltage scheme, but other configurations are possible.

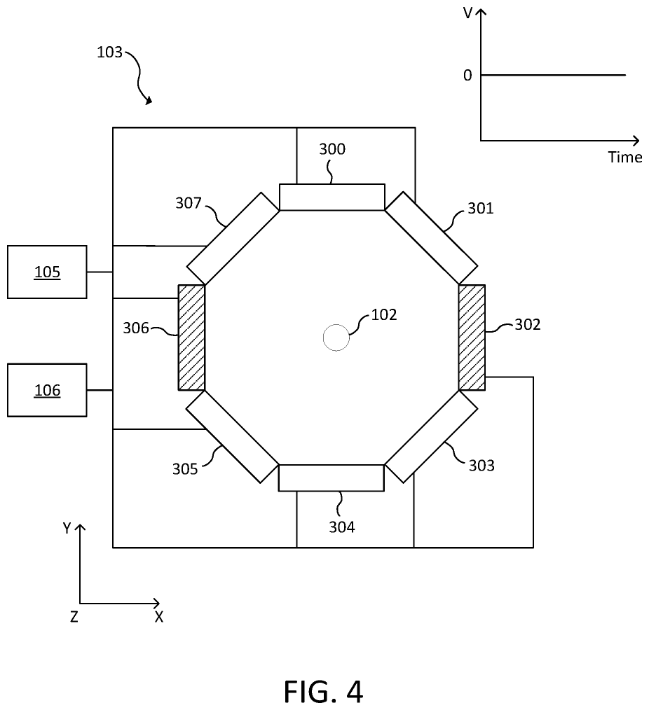

FIGS. 4-6 include a voltage charts showing operation of the multichannel electrode tube corresponding to the embodiment of FIG. 3. In FIG. 4, the electron beam 102 is in a center of the multichannel electrode tube 103. A chart shows the voltage over time. In this example, the voltage (V) is a difference between the voltage of deflection plate 302 and deflection plate 306 (which are shaded). The electron beam 102 is centered between the deflection plate 302 and the deflection plate 306. Therefore, the voltage is illustrated on the chart at zero. The voltage difference will become positive or negative as the electron beam 102 moves away from the center. Thus, the voltage difference corresponds to a position of the electron beam 102 in the multichannel electrode tube 103. The processor 106 can be used to determine this voltage difference.

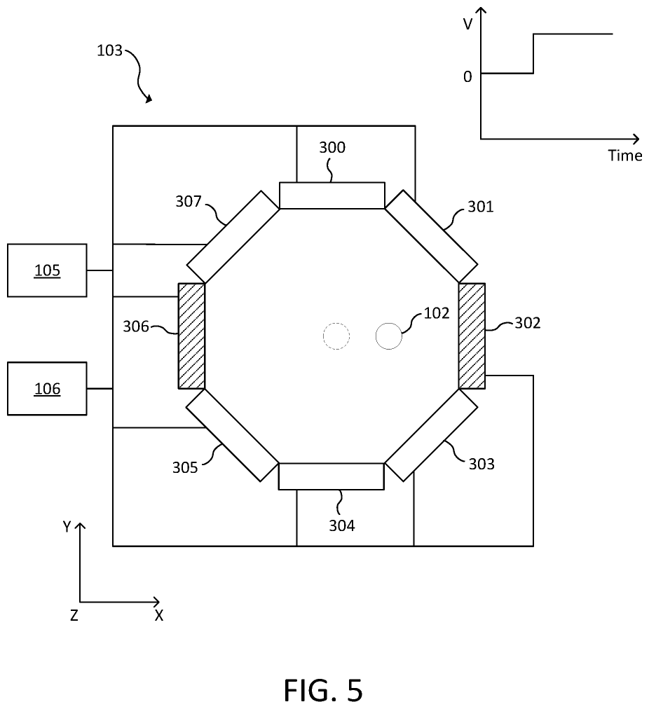

In FIG. 5, the electron beam 102 moves to the right relative to its previous position in FIG. 4 (shown in dotted lines). The electron beam 102 is now more proximate the deflection plate 302 than the deflection plate 306. This changes the voltage difference, as illustrated in the chart. The voltage difference is positive after the movement of the electron beam 102. The processor 106 can be used to determine this voltage difference.

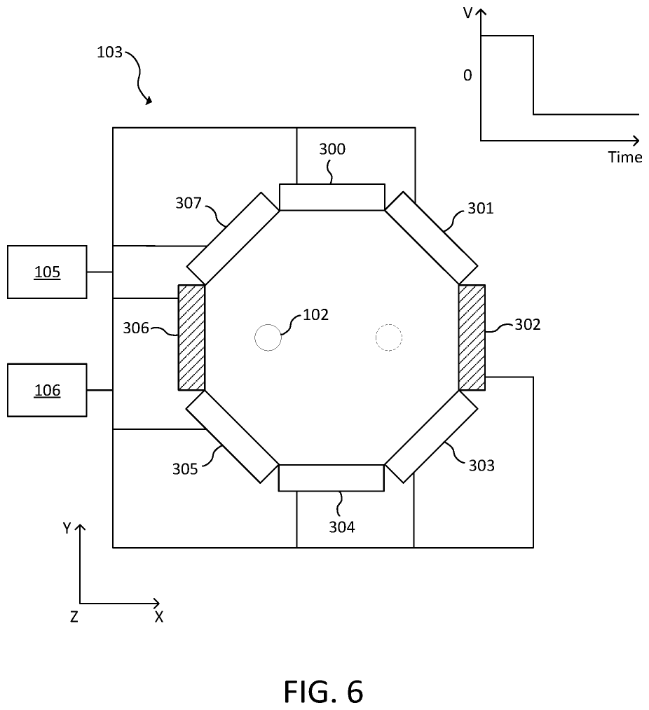

In FIG. 6, the electron beam 102 moves to the left relative to its previous position in FIG. 5 (shown in dotted lines). The electron beam 102 is now more proximate the deflection plate 306 than the deflection plate 302. This changes the voltage difference, as illustrated in the chart. The voltage difference is negative after the movement of the electron beam 102. The processor 106 can be used to determine this voltage difference.

While illustrated with two of the deflection plates, a voltage difference can be determined for two or more pairs of deflection plates to give a two-dimensional measurement of the position of the electron beam 102 in the cross-section of the multichannel electrode tube 103 (e.g., the x-y plane). Each pair of deflection plates can provide a linear determination of the position of the electron beam 102.

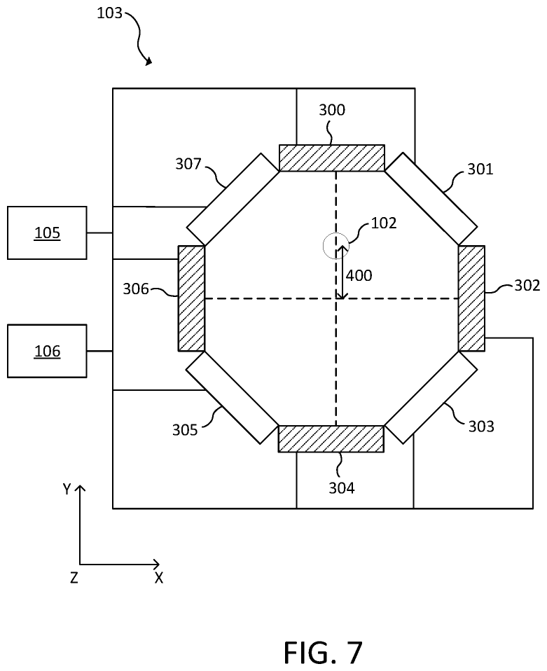

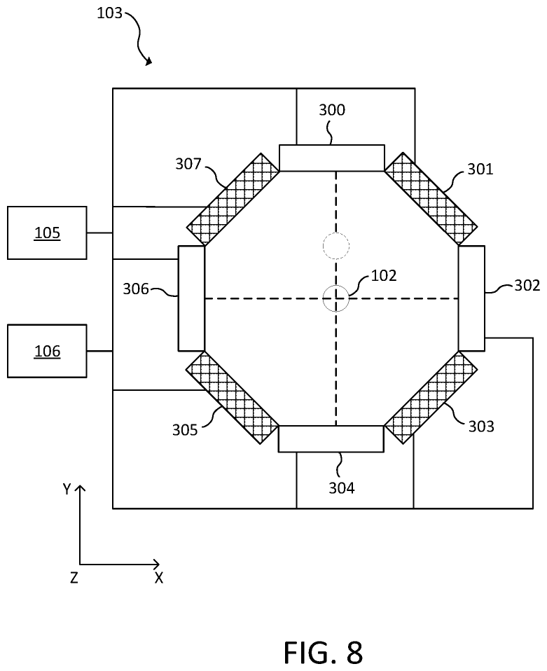

FIGS. 7 and 8 include charts showing operation of the multichannel electrode tube corresponding to the embodiment of FIG. 3. FIGS. 7 and 8 include a grid to show a center of the multichannel electrode tube 103 in two dimensions. The center of the multichannel electrode tube 103 can be a position specification for the electron beam 102 in the multichannel electrode tube 103.

Of course, other position specifications for the electron beam 102 are possible. The position specification need not only be in the center of the multichannel electrode tube 103 or the center of an area inside the deflection plates. The position specification can depend on the imaging application for the electron beam 102, the type of workpiece being imaged, the configuration of the system, calibration of other optical components in the system, or other variables.

In FIG. 7, the processor 106 determines a position of the electron beam 102 in the multichannel electrode tube 103. For example, the voltage difference between the deflector plates 300, 302, 304, and 306 (shaded in FIG. 7) can be used to determine the position of the electron beam 102. In FIG. 7, the path of the electron beam 102 is equally positioned between deflector plates 302 and 306, which meets the position specification in the horizontal axis. However, the path of the electron beam 102 does not meet the position specification in the vertical axis between deflection plate 300 and deflection plate 304. The electron beam 102 is more proximate to deflection plate 300 than deflection plate 304. The gap between the electron beam 102 and the position specification is shown with an arrow 400.

The gap between the electron beam 102 can be measured between a center of the electron beam 102 or a perimeter of the electron beam 102. The center of the electron beam 102 is used in the example of FIGS. 7-8.

The processor 106 then can determine a voltage scheme for the multichannel electrode tube 103 to direct the electron beam 102 to the position specification. As shown in FIG. 8, a different voltage is applied to deflection plates 301, 303, 305, and 307 to direct the electron beam 102 from the previous position (shown in dotted lines) to the position specification at the center of the grid. In an instance, this is a voltage that minimizes the voltage difference until it is zero. This activity can be part of a control loop to maintain the electron beam 102 at the position specification by minimizing the voltage difference or rendering the voltage difference to be zero. The processor 106 can change the voltage scheme until the electron beam 102 is at the position specification.

In the example of FIGS. 7 and 8, different pairs of deflection plates are used to measure the voltages for the voltage difference and for application of the voltage scheme.

An additional embodiment relates to a non-transitory computer-readable medium storing program instructions executable on a processor for performing a computer-implemented method of electron beam calibration, as disclosed herein. The processor 106 can include a memory in an electronic data storage unit or other electronic data storage medium with non-transitory computer-readable medium that includes program instructions executable on the processor 106. The computer-implemented method may include any step(s) of any method(s) described herein. For example, the processor 106 may be programmed to perform some or all of the steps of FIGS. 4-6 or FIGS. 7-8. In an instance, the processor 106 may receive voltage measurements for a pair of deflection plates in a multichannel electrode tube as an electron beam is directed through the multichannel electrode tube. Each of the deflection plates is disposed opposite another of the deflection plates across a path of the electron beam. The processor 106 may then determine a voltage difference between of the pair of the deflection plates and determine a position of the electron beam in the multichannel electrode tube based on the voltage. The processor 106 also can determine a gap between the position of the electron beam in the multichannel electrode tube and a position specification for the electron beam in the multichannel electrode tube; determine a voltage scheme for the multichannel electrode tube that directs the electron beam to the position specification; and send instructions to apply the voltage scheme to the deflection plates. The memory in the electronic data storage unit or other electronic data storage medium may be a storage medium such as a magnetic or optical disk, a non-volatile memory, a solid-state memory, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (MFC), Streaming SIMD Extension (SSE), or other technologies or methodologies, as desired.

While disclosed with respect to electron beams, the embodiments disclosed herein also can be used with ion beams. The electron beam source may be replaced with any suitable ion beam source known in the art. In addition, the output acquisition subsystem may be any other suitable ion beam-based output acquisition subsystem such as those included in commercially available focused ion beam (FIB) systems, helium ion microscopy (HIM) systems, and secondary ion mass spectroscopy (SIMS) systems. Thus, various particle beams can benefit from the embodiments disclosed herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron beam source that generates an electron beam;
a stage configured to hold a workpiece in a path of the electron beam;
a multichannel electrode tube that includes at least four deflection plates, wherein each of the deflection plates is disposed opposite another of the deflection plates across the path of the electron beam in the multichannel electrode tube;
a power source in electronic communication with the deflection plates; and
a processor in electrical communication with the deflection plates, wherein the processor is configured to:
determine a voltage difference between of a pair of the deflection plates that are arranged opposite each other across the path of the electron beam; and
determine a position of the electron beam in the multichannel electrode tube based on the voltage difference.

2. The system of claim 1, wherein the deflection plates are arranged as a square around the path of the electron beam.

3. The system of claim 1, wherein there are eight of the deflection plates.

4. The system of claim 3, wherein the deflection plates have an octagonal configuration around the path of the electron beam.

5. The system of claim 1, wherein the position is in a cross-sectional plane of the multichannel electrode tube perpendicular to the path of the electron beam.

6. The system of claim 1, wherein the processor is further configured to:
determine a gap between the position of the electron beam in the multichannel electrode tube and a position specification for the electron beam in the multichannel electrode tube;
determine a voltage scheme for the multichannel electrode tube that directs the electron beam to the position specification; and
send instructions to the power source to apply the voltage scheme to the deflection plates.

7. The system of claim 6, wherein the position specification is a center of the multichannel electrode tube.

8. The system of claim 6, wherein two of the deflection plates are used to measure voltages for the voltage difference and a different two of the deflection plates receive the voltage scheme.

9. A method comprising:
generating an electron beam using an electron beam source;
directing the electron beam toward a workpiece on a stage;
directing the electron beam through a multichannel electrode tube, wherein the multichannel electrode tube includes at least four deflection plates, and wherein each of the deflection plates is disposed opposite another of the deflection plates across a path of the electron beam;
determining a voltage difference between of a pair of the deflection plates that are arranged opposite each other across the path of the electron beam; and
determining, using a processor, a position of the electron beam in the multichannel electrode tube based on the voltage difference.

10. The method of claim 9, wherein the deflection plates are arranged as a square around the path of the electron beam.

11. The method of claim 9, wherein there are eight of the deflection plates.

12. The method of claim 11, wherein the deflection plates have an octagonal configuration around the path of the electron beam.

13. The method of claim 9, wherein the position is in a cross-sectional plane of the multichannel electrode tube perpendicular to the path of the electron beam.

14. The method of claim 9, wherein the method further includes:
determining, using the processor, a gap between the position of the electron beam in the multichannel electrode tube and a position specification for the electron beam in the multichannel electrode tube;
determining, using the processor, a voltage scheme for the multichannel electrode tube that directs the electron beam to the position specification; and
applying the voltage scheme to the deflection plates.

15. The method of claim 14, wherein the position specification is a center of the multichannel electrode tube.

16. The method of claim 14, wherein two of the deflection plates are used to measure voltages for the voltage difference and a different two of the deflection plates are used with the voltage scheme.

17. A non-transitory computer-readable storage medium, comprising one or more programs for executing the following steps on one or more computing devices:
receiving voltage measurements for a pair of deflection plates in a multichannel electrode tube as an electron beam is directed through the multichannel electrode tube, wherein each of the deflection plates is disposed opposite another of the deflection plates across a path of the electron beam;
determining a voltage difference between of the pair of the deflection plates; and
determining a position of the electron beam in the multichannel electrode tube based on the voltage.

18. The non-transitory computer-readable storage medium of claim 17, wherein the steps further include:
determining a gap between the position of the electron beam in the multichannel electrode tube and a position specification for the electron beam in the multichannel electrode tube;
determining a voltage scheme for the multichannel electrode tube that directs the electron beam to the position specification; and
sending instructions to apply the voltage scheme to the deflection plates.
